(19) United States
(12) Patent Application Publication
(10) Pub. No.: US 2011/0240113 A1
(43) Pub. Date: Oct. 6, 2011

(54) SOLAR CELL STRUCTURE

(75) Inventors: TING FANG, TAINAN (TW); KANG-CHENG LIN, TAIPEI COUNTY (TW)

(73) Assignee: MOTECH INDUSTRIES INC., New Taipei City (TW)

(21) Appl. No.: 13/028,466

(22) Filed: Feb. 16, 2011

(30) Foreign Application Priority Data
Apr. 1, 2010 (TW) 099110249

(51) Int. Cl. H01L 31/0232

(52) U.S. Cl. 136/256

(57) ABSTRACT

A solar cell structure includes a silicon crystal having at least one slant penetrating hole, the penetrating hole internally having at least one inclined surface; an emitter covering the silicon crystal and the inclined surface in the penetrating hole; and a first metal electrode being electrically connected to the emitter and located in the penetrating hole of the silicon crystal at a bottom thereof. By forming the inclined surface having an inclination angle in the slant penetrating hole, light incident upon the inclined surface of the penetrating hole can have a length-increased optical path in the solar cell to thereby enhance the photocurrent of the solar cell.

### FIELD OF THE INVENTION

The present invention relates to a solar cell structure, and more particularly to a solar cell structure having slant penetrating holes formed on a silicon crystal thereof to provide inclined surfaces in the holes for reflecting and thereby increasing the optical path of incident light in the solar cell.

### BACKGROUND OF THE INVENTION

Currently, while an emitter wrap through (EWT) back-contact solar cell can avoid light-shielding by a metal gate on a front side of the solar cell to enable increased amount of incident sunlight, forward current has to flow through the emitter via a plurality of holes penetrating the surface of the emitter and the crystal before the forward current is converged at a back side of the cell. Therefore, a large quantity of holes is needed to serve as convergence channel. The holes penetrating the crystal are usually perpendicular to the surface of the crystal. When the incident light is incident on positions with the holes, the incident light is almost completely reflected by the metal at the bottom of the holes. This would cause optical loss of light and result in only very limited enhancement of the photocurrent.

FIG. 1 is a cross-sectional view of a conventional solar cell structure. As shown, the conventional solar cell structure includes a silicon crystal 10 penetrated by at least one hole and a metal electrode 30. The silicon crystal 10 internally has opposite surfaces 11, 21 that are parallel to each other and perpendicular to a top surface of the silicon crystal 10 in the hole. As indicated by the two-headed arrows, the light incident on a position of the silicon crystal 10 with the hole is almost completely reflected by the metal electrode 30 located in the hole at a bottom thereof. This causes optical loss of light and the photocurrent of the solar cell could not be effectively enhanced.

### SUMMARY OF THE INVENTION

A primary objective of the present invention is to provide a solar cell structure characterized by a silicon crystal with slant penetrating holes having an inclination angle each.

To achieve the above and other objectives, the solar cell structure according to the present invention includes a silicon crystal being penetrated by at least one slant hole, and the slant hole internally has at least one inclined surface. The solar cell structure further includes an emitter and a first metal electrode. The emitter covers a top surface, the inclined surface, and part of a bottom surface of the silicon crystal. The solar cell structure further includes an anti-reflection layer covering the emitter located on the top surface of the silicon crystal and the inclined surface. The first metal electrode is located in the slant hole at a bottom thereof and is electrically connected to the emitter.

By providing the inclined surface having an inclination angle in the slant hole, light incident upon the inclined surface is reflected in the slant hole to thereby have increased optical path in the solar cell and accordingly enhance the photocurrent of the solar cell.

With the above arrangements, the solar cell structure according to the present invention has one or more of the following advantages:

(1) The solar cell structure allows incident light to be reflected several times in the slant hole and therefore have increased optical path in the solar cell.

(2) With the inclined surface formed in the slant hole on the silicon crystal, the photocurrent of the solar cell is enhanced.

### BRIEF DESCRIPTION OF THE DRAWINGS

The structure and the technical means adopted by the present invention to achieve the above and other objectives can be best understood by referring to the following detailed description of the preferred embodiments and the accompanying drawings, wherein

FIG. 1 is a cross-sectional view of a conventional solar cell structure;

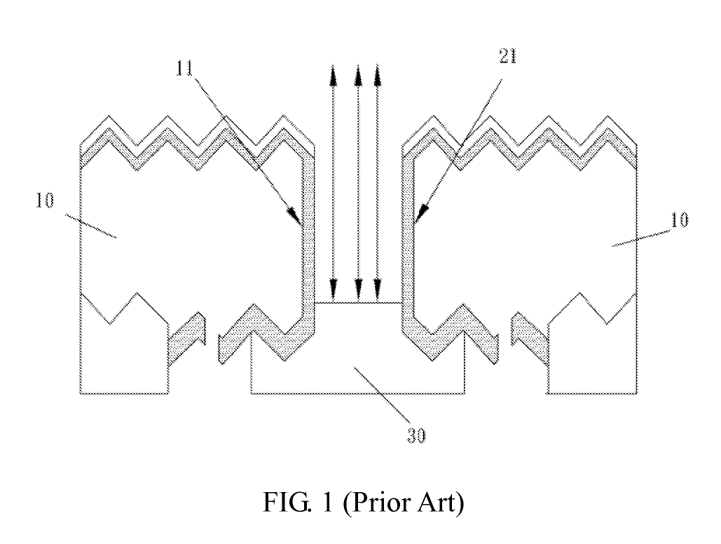

FIG. 2 is a cross-sectional view of a solar cell structure according to a preferred embodiment of the present invention;

FIG. 3 is a top view of the solar cell structure according to the preferred embodiment of the present invention shown in FIG. 2; and

FIG. 4 is a cross-sectional view showing the solar cell structure according to the preferred embodiment of the present invention in use.

### DETAILED DESCRIPTION OF THE PREFERRED EMBODIMENTS

The present invention will now be described with a preferred embodiment thereof For the purpose of easy to understand, elements that are the same in the preferred embodiment are denoted by the same reference numeral.

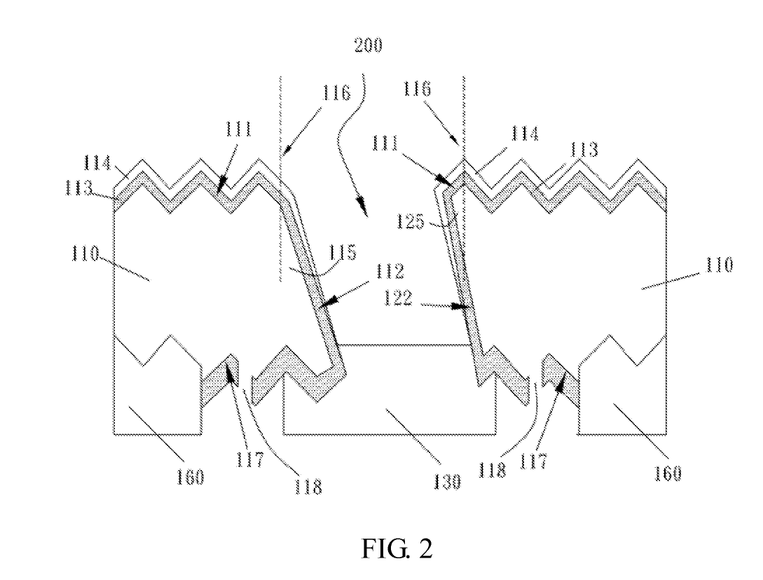

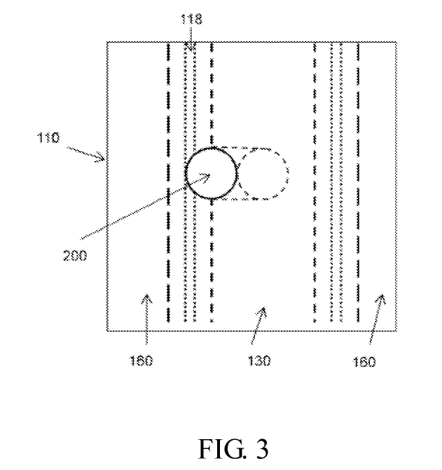

Please refer to FIGS. 2 and 3 that are cross-sectional view and top view, respectively, of a solar cell structure according to a preferred embodiment of the present invention. As shown in FIG. 2, the solar cell structure includes a silicon crystal 110 being penetrated by at least one slant hole 200. The silicon crystal 110 has at least one inclined surface in the slant hole 200. The inclined surface has a first area 112 and a second area 122. The solar cell structure further includes an emitter 113 and a first metal electrode 130. The emitter 113 covers a top surface 111, the inclined surface, and part of a bottom surface 117 of the silicon crystal 110. The solar cell structure according to the present invention further includes an anti-reflection layer 114, which covers the emitter 113 located on the top surface 111 and the inclined surface of the silicon crystal 110. The first metal electrode 130 is located in the slant hole 200 at a bottom thereof, and is electrically connected to the emitter 113. As shown in FIGS. 2 and 3, for a P-type silicon crystal, the first metal electrode 130 is a negative pole, and a second metal electrode 160 located at the bottom surface 117 of the silicon crystal 110 is a positive pole. The first metal electrode 130 and the second metal electrode 160 are isolated from each other by an insulating structure 118, which can be, for example, an insulating groove, an insulating layer or an insulating member. Alternatively, the insulating structure 118 can be formed simply by removing a portion of the emitter 113 that is nearby the second metal electrode 160. However, it is understood, in the present invention, the insulating structure 118 can be formed or provided in other manners without being limited to the above-mentioned types. Further, in the description of the present invention herein, only one slant hole 200 on the silicon crystal 110 is illustrated. However, it is understood a plurality of penetrated slant holes 200 can be provided on the silicon crystal 110.

The first area 112 of the inclined surface in the slant hole 200 is a surface having an inclination angle. The inclination angle is measured based on a direction of a normal line 116 perpendicular to the top surface 111 of the silicon crystal 110. A first angle 115 is contained between the first area 112 of the inclined surface and the normal line 116, and is larger than negative 90 degree and smaller than 90 degree. Similarly, based on the direction of the normal line 116 perpendicular to the top surface 111 of the silicon crystal 110, a second angle 125 is contained between the second area 122 of the inclined surface and the normal line 116, and is larger than negative 90 degree and smaller than 90 degree. The first angle 115 and the second angle 125 can be the same with or different from each other. It is understood the inclination angle illustrated in the drawings is only an example, and any angle contained between the normal line 116 and the first area 112 or the second area 122 of the inclined surface that falls in the range of the inclination angle defined by the present invention is within the spirit and scope of the present invention. The slant hole 200 can be formed by laser drilling, such that the first area 112 and the second area 122 of the inclined surface in the slant hole 200 have different inclination angles. The hole formed by laser drilling can have a size ranged between 10 μm and 200 μm. The resultant inclination angles might vary with different processing manners. In the present invention, the slant hole 200 can be formed by laser drilling without being limited thereto. Any change and modification in the described manner of forming the slant hole 200 carried out without departing from the scope and the spirit of the invention shall be included in the appended claims, only by which the present invention is limited.

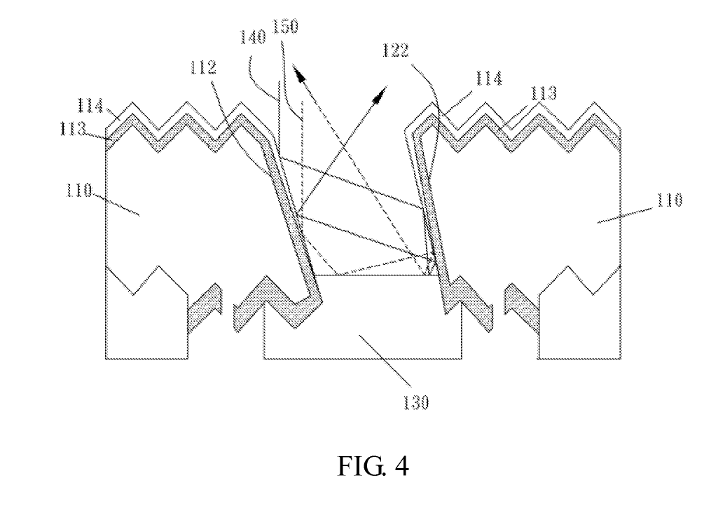

Please refer to FIG. 4 that is a cross-sectional view showing the solar cell structure according to the preferred embodiment of the present invention in use. As shown in FIG. 4, a first incident light 140 is reflected five times in the slant hole 200. More specifically, the first incident light 140 is reflected twice by the anti-reflection layer 114 on the first area 112 of the inclined surface, twice by the anti-reflection layer 114 on the second area 122 of the inclined surface, and once by the first metal electrode 130. Meanwhile, a second incident light 150 is reflected four times in the slant hole 200. More specifically, the second incident light 150 is reflected once by the anti-reflection layer 114 on the first area 112 of the inclined surface, once by the anti-reflection layer 114 on the second area 122 of the inclined surface, and twice by the first metal electrode 130. With the first area 112 and the second area 122 of the inclined surface respectively having an inclination angle, light incident upon the slant hole 200 can be reflected several times to thereby increase the optical path of the incident light in the solar cell structure and accordingly, enhance the photocurrent of the solar cell.

The above described solar cell can be an N-type or a P-type polycrystalline or monocrystalline solar cell. In the illustrated preferred embodiment, the solar cell structure is an emitter wrap through (EWT) back-contact solar cell for enhancing the photocurrent of the solar cell.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A solar cell structure, comprising:
a silicon crystal having at least one penetrating hole, the penetrating hole internally having
at least one inclined surface, such that light incident upon the penetrating hole is reflected
at least once by the inclined surface;
an emitter covering the silicon crystal and the inclined surface in the penetrating hole; and
a first metal electrode being electrically connected to the emitter and located in the penetrating hole of the silicon crystal at a bottom thereof, and the incident light being reflected at least onto the first metal electrode.

2. The solar cell structure as claimed in claim 1, wherein the inclined surface and a normal line perpendicular to a top surface of the silicon crystal together contain an angle, and the angle being larger than negative 90 degree and smaller than 90 degree.

3. The solar cell structure as claimed in claim 1, wherein the silicon crystal is selected from the group consisting of N-type polycrystalline silicon, P-type polycrystalline silicon, N-type monocrystalline silicon, and P-type monocrystalline silicon.

4. The solar cell structure as claimed in claim 1, further comprising a second metal electrode located at a bottom of the silicon crystal.

5. The solar cell structure as claimed in claim 4, wherein the first metal electrode and the second metal electrode are isolated from each other by an insulating structure.
